(19) United States
(12) Patent Application Publication
(10) Pub. No.: US 2009/0102052 A1
(43) Pub. Date: Apr. 23, 2009

(54) Semiconductor Device and Fabricating Method Thereof

(76) Inventor: Sang Wook RYU, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/254,719

(22) Filed: Oct. 20, 2008

(30) Foreign Application Priority Data
Oct. 22, 2007 (KR) 10-2007-0106052

(51) Int. Cl. H01L 23/52; H01L 21/44

(52) U.S. Cl. 257/751; 438/653; 257/E21.476

(57) ABSTRACT

A semiconductor device and fabricating method thereof are disclosed. The method includes forming a first metal line over a substrate, forming a barrier layer over the substrate and the first metal line, forming an insulating layer on the barrier layer, forming a capping layer on the insulating layer, forming a photoresist pattern on the capping layer, implanting halogen ions into the insulating layer using the photoresist pattern as a mask, forming a via-hole exposing the first metal line by dry-etching the insulating layer using the photoresist pattern as an etch mask, and forming a second metal line in the via-hole in contact with the first metal line.

This application claims the benefit of the Korean Patent Application No. P2007-0106052, filed on Oct. 22, 2007 which is hereby incorporated by reference as if fully set forth herein.

### BACKGROUND OF THE INVENTION

1. Field of the Invention

The present invention relates to a semiconductor device, and more particularly, to a semiconductor device and fabricating method thereof. Although the present invention is suitable for a wide scope of applications, it is particularly suitable for a dual damascene pattern and a method of forming the same.

2. Discussion of the Related Art

Generally, a main etch gas in dry etching an insulating layer is based on CₓH_{y}F_{z} (where x is an integer of at least 1, and y and z are each zero or natural number equal to 2x or 2x+2). Oxygen (O₂) gas may be used for C/F ratio adjustment or another purpose. Nitrogen gas (N₂), which has volatility lower than that of oxygen gas and generates etch residues, is used. And, Ar gas or the like may be used for plasma dilution, uniformity enhancement and derivation of anisotropic dry etch by ionization.

Yet, since a density of via holes is usually less than 1% of a whole wafer area, a difference of etch residue quantity can be generated between a dense via-hole area and a sparse via-hole area on the wafer.

Therefore, due to the carbon component generated from photoresist and the difference of the etch residue as a function of via hole density, an etch rate of the dense via-hole area increases while an etch rate of an edge of the dense via-hole area (e.g., an area adjacent to a photoresist-covered area) decreases. This is because the C/F ratio has a local difference due to the injected gas. In particular, if there is a considerable quantity of an insulating layer to be etched, and if a photoresist area is locally small, the C/F ratio is lowered to raise an etch rate. On the contrary, if there is a considerable quantity of photoresist, an etch rate of the corresponding exposed insulator part is lowered. Hence, the etch rate may be significantly reduced, and in an extreme case, the etch may be stopped. Consequently, a metal line may be disconnected, which can cause a malfunction of the device. Specifically, such a phenomenon mainly takes place in case of using a gas having a high C/F ratio (e.g., C₄F₈, C₅F₈, C₆F₈, etc.), often used to implement a high etch selectivity ratio for the insulator relative to a lower layer. In particular, the above phenomenon barely takes place when using an etch gas such as CF₄ and the like.

### SUMMARY OF THE INVENTION

Accordingly, the present invention is directed to a semiconductor device and fabricating method thereof that substantially obviate one or more problems due to limitations and disadvantages of the related art.

An object of the present invention is to provide a semiconductor device and fabricating method thereof, by which disconnection of metal lines and operational malfunction of a device can be prevented by reducing or preventing the occurrence of local deviation of a C/F ratio in case of etching an insulating layer.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a semiconductor device according to the present invention includes the steps of forming a first metal line over a substrate, forming a barrier layer over the substrate and the first metal line, forming an insulating layer on the barrier layer, forming a capping layer on the insulating layer, forming a photoresist pattern on the capping layer, implanting halogen-containing ions into the insulating layer using the photoresist pattern as an ion implantation mask, forming a via-hole exposing the first metal line by dry-etching the insulating layer using the photoresist pattern as an etch mask, and forming a second metal line in the via-hole in contact with the first metal line.

In another aspect of the present invention, a semiconductor device includes a Cu line over a substrate, a barrier layer over the substrate and the Cu line, an insulating layer on the barrier layer, the insulating layer comprising at least one halogen ion implanted and distributed therein, a capping layer on the insulating layer, and a second Cu line in contact with the first Cu line and penetrating the barrier layer, the insulating layer and the capping layer.

Accordingly, a semiconductor device and fabricating method thereof according to the present invention reduces or prevents local deviations of the C/F ratio when forming a via-hole, thereby preventing etch inferiority and metal line disconnection.

It is to be understood that both the foregoing general description and the following detailed description of the present invention are exemplary and explanatory and are intended to provide further explanation of the invention as claimed.

### BRIEF DESCRIPTION OF THE DRAWINGS

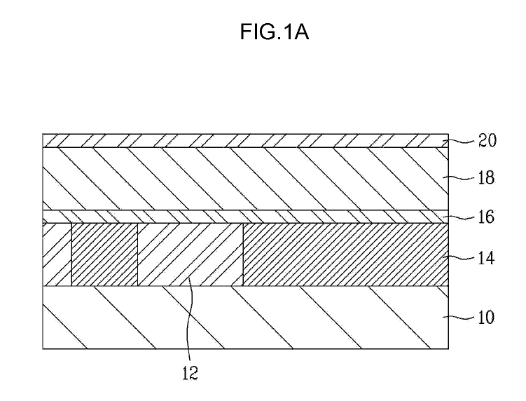

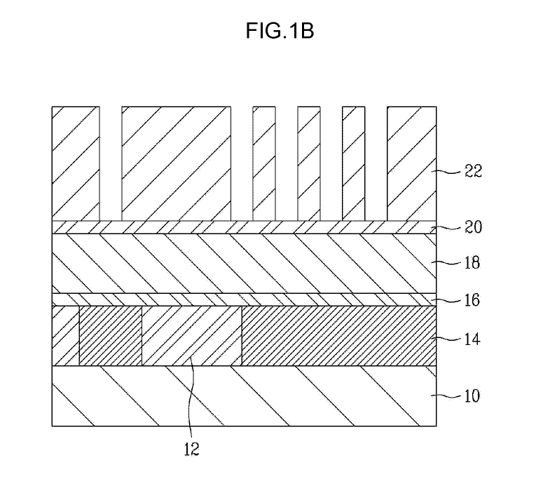

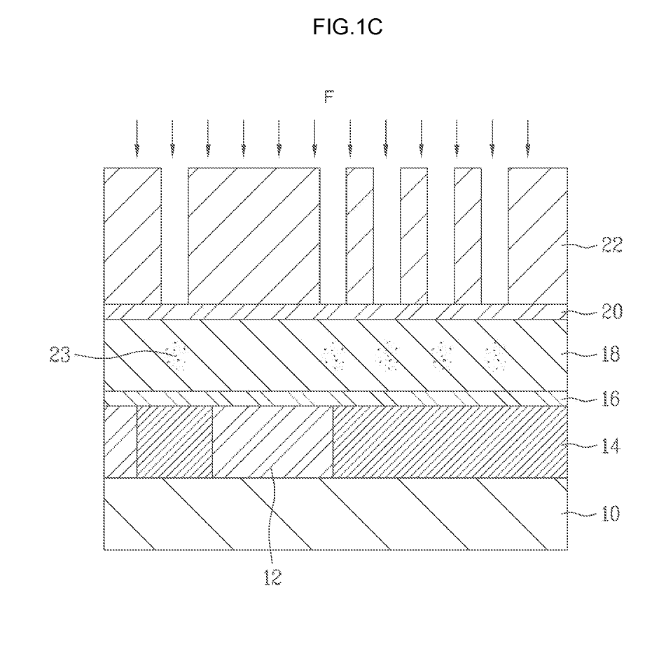

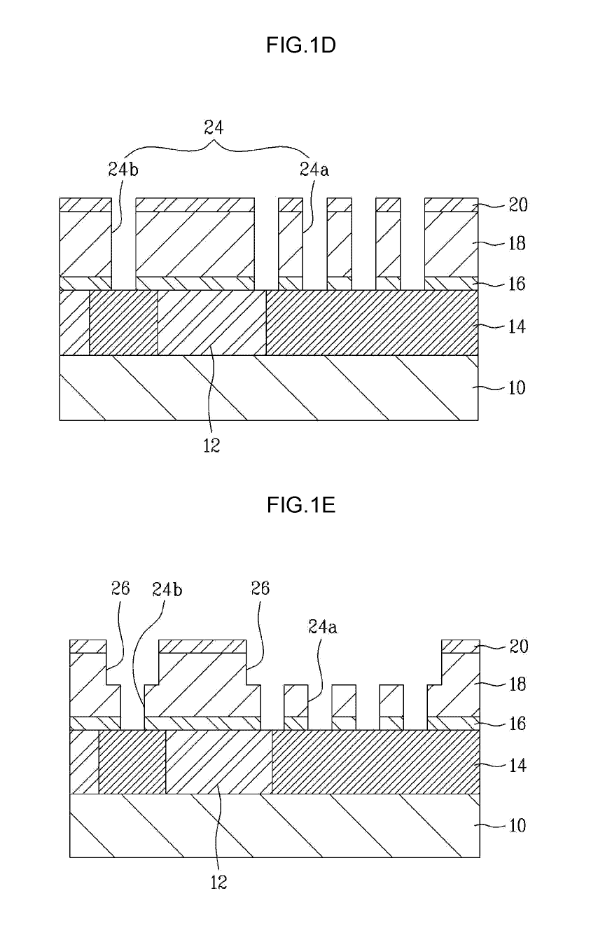

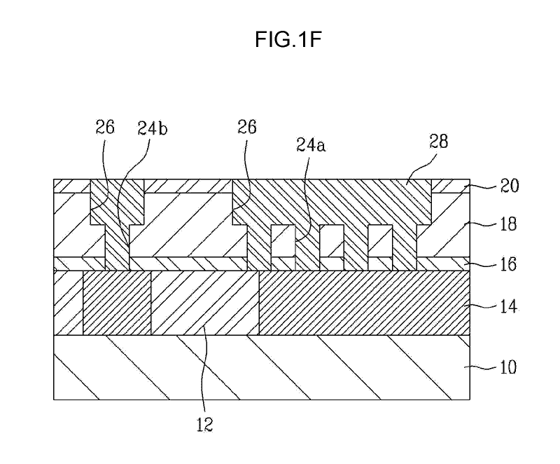

The accompanying drawings, which are included to provide a further understanding of the invention and are incorporated in and constitute a part of this application, illustrate embodiment(s) of the invention and together with the description serve to explain the principle(s) of the invention. In the drawings, FIGS. 1A to 1F are cross-sectional diagrams of exemplary structures made by a method of fabricating a semiconductor device according to embodiments of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

In particular, saying that a first part of a layer, film, area, plate or the like is provided, deposited or formed ‘over’ a second part includes a case where one or more third parts are inserted between the first and second part, as well as a case where the first part is provided on the second part. Moreover, saying that a first part is provided, deposited or formed ‘onto’ a second part means a case that nothing lies between the first and second parts.

FIGS. 1A to 1F are cross-sectional diagrams for explaining an exemplary method of fabricating a semiconductor device according to embodiments of the present invention.

Referring to FIG. 1A, a first insulating layer 12 is formed over a substrate 10, and a first Cu line 14 is formed in the first insulating layer 12. For instance, after a photoresist pattern (not shown in the drawing) has been formed on the first insulating layer 12 by photolithography, a trench (not shown in the drawing) is formed by etching the first insulating layer 12 using the photoresist pattern as an etch mask. The first Cu line 14 is then formed by filling the trench with Cu.

The insulating layer 12 may comprise a lowermost etch stop layer (e.g., silicon nitride), a bulk dielectric layer (e.g., one or more silicon oxide layers doped with boron and/or phosphorous [BSG, PSG and/or BPSG] or a low-k dielectric, such as a fluorosilicate glass [FSG], silicon oxycarbide [SiOC] or hydrogenated silicon oxycarbide [SiOCH], any of which may comprise upper and lower bulk/ low-k dielectric layers above and below an intermediate etch stop layer [e.g., silicon nitride]), and a capping layer (e.g., of TEOS, USG, a plasma silane [e.g., silicon dioxide formed by plasma-assisted CVD of silicon dioxide from silane and oxygen], silicon nitride, or a combination thereof, such as a bilayer of silicon nitride on USG or TEOS, or a bilayer of USG on TEOS). The copper line 14 may comprise a single or dual damascene copper line, which may further include an adhesive and/or barrier layer between it and the dielectric (e.g., a Ta/TaN bilayer). The adhesive and/or barrier layer may be formed by sputtering, evaporation or chemical vapor deposition (CVD), and the copper may be deposited by electroplating or electroless plating (optionally onto a sputtered or evaporated copper seed layer).

Subsequently, a barrier layer 16 for preventing diffusion, a second insulating layer 18 and a capping layer 20 are sequentially formed over the first insulating layer 12 including the first CU line 14. The barrier layer 16 can include a single layer comprising or consisting essentially of at least one of silicon carbide (SiC), Si₃N₄, SiOC, SiOCH and silicon oxynitride (SiON), or at least two layers stacked on each other where at least one (and optionally all) of the layers comprises or consists essentially of SiC, Si₃N₄, SiOC, SiOCH and SiON. In this case, the barrier layer 16 can be 100˜1,500 Å thick.

The second insulating layer 18 can include an OSG (Organic Silicate Glass) layer and be formed by spin coating. In this case, the OSG may include SiOCH and/or SiOCH₃ (e.g., methyl silsesquioxane, or MSQ). The OSG layer is a low-k insulating layer and generally has F, C or CH₃ at least partially bonded to Si and/or O in what would otherwise be SiO₂.

In various embodiments, the OSG substance has a dielectric constant of 2.0˜2.8. Hence, the dielectric constant of the OSG substance can be considerably lower than that of USG (Undoped Silica Glass: 4.2) or FSG (Fluorine doped Silica Glass: 3.5). The dielectric constant may be lowered by bonding carbon or a hydroxyl functional group at least partially to one or more atoms of the Si—O bond. In some embodiments, the OSG substance may function as an etch-stop due to a considerable quantity of photoresist existing around an isolated via-hole according to a local pattern density.

The capping layer 20 can include a single or stacked layer including at least one of SiO₂, SiC, SiN (Si₃N₄), SiOC, SiOCH and SiON. The capping layer 20 plays a role as an anti-reflective layer, a CMP stop layer in CMP (chemical mechanical polishing), or a buffer for ion implantation.

Referring to FIG. 1B, photoresist is deposited on the capping layer 20 to form a photoresist layer. The photoresist layer is then exposed and developed to form a photoresist pattern 22. In one embodiment, the photoresist layer is formed using an anti-reflective layer (e.g., the capping layer 20).

The photoresist pattern 22 is defined for via-hole formation. The first photoresist pattern can be formed to define a dense via-hole area and an isolated via-hole area. In this case, portions of the photoresist pattern for defining the dense via-hole area and the isolated via-hole area are named first and second pattern areas, respectively. The first pattern area has a plurality (e.g., 4) of exposed portions for locally exposing a surface of the capping layer 20, while the second pattern area has less exposed portions (e.g., a single exposed portion) for locally exposing the surface of the capping layer 20.

Referring to FIG. 1C, using the photoresist pattern as an ion implantation mask, the second insulating layer 18 is doped with at least one halogen element or ion, including F, Cl, Br and the like. The dose of such halogen ion(s)/element(s) may be in the range of 1E5˜1E18 (e.g., 1E15˜1E18), and the energy may be in the range of 5˜100 KeV. In this case, by varying the energy and dose of the ion implantation, it is possible to provide a uniform depth of ion distribution. Sources of such halogen ions may include the elemental halogens themselves (e.g., F₂, Cl₂, Br₂) and relatively low molecular weight compounds (e.g., in the gas or liquid state at ambient temperatures) including halogen atoms and one or more atoms of the second insulating layer 18 (e.g., CF₄, CH₃Cl, CH₃F, CHCl₃, SiF₄, SiCl₄, NF₃, C(═O) Cl₂, (C═O)₂F₂, HOCl, Cl₂O, HF, etc.).

In this case, although the ion distribution of the halogen element within the second insulating layer 18 is relatively dense in the first pattern area, the ion distribution of the halogen element in the second insulating layer 18 is not so dense in the second pattern area.

Referring to FIG. 1D, using the photoresist pattern 22 as an etch mask, the capping layer 20, the second insulating layer 18 and the barrier layer 16 are etched to form via-holes 24 making the first Cu line 14 exposed. Subsequently, the remaining photoresist pattern 22 is removed.

By an etch process using the first pattern area, dense via-holes 24a are formed. By an etch process (e.g., the same etch process as for the first pattern area) using the second pattern area, an isolated via-hole 24b is formed. In this case, the etch can be performed by dry (plasma) etching using CₓH_{y}F_{z} (where x, y, and z are each independently 0 or natural number; preferably where x is an integer of 1 or more, such as from 1 to 5; [y+z]=2x+2 or, when x is an integer of at least 2, 2x; and z is 0, 1 or 2) as a main etchant. Optionally, an additive gas comprising or consisting essentially of O₂, N₂, Ar, He or the like may be added to the main etchant. Therefore, even when a local C/F ratio deviation can be generated between the dense via-holes 24a and the isolated via-hole 24b, since the halogen element having strong reactivity is in the insulating layer 18 (e.g., in locations that are subject to etching to form via holes 24a and 24b), the present invention is able to reduce or prevent an excessive C/F ratio increase around the isolated via-hole and the corresponding etch-stop effect.

Referring to FIG. 1E, a photoresist pattern (not shown in the drawing) for forming a trench is formed. A trench 26 is then formed over the via-holes 24a-b using the photoresist pattern as an etch mask.

Referring to FIG. 1F, a second metal line 28 is formed in the via-holes and the trench to form the second metal line in the trench and contacts with the first metal line 14 in the vias. The CMP is then performed on the topside of the second metal line 28 for planarization. The second metal line 28 may comprise the same materials, optionally in the same order, as the first metal line 14.

It will be apparent to those skilled in the art that various modifications and variations can be made in the present invention without departing from the spirit or scope of the inventions. Thus, it is intended that the present invention covers modifications and variations of this invention, provided they come within the scope of the appended claims and their equivalents.

What is claimed is:

1. A method of fabricating a semiconductor device, comprising the steps of:
forming a first metal line over a substrate;
forming a barrier layer over the substrate and the first metal line;
forming an insulating layer on the barrier layer;
forming a capping layer on the insulating layer;
forming a photoresist pattern on the capping layer;
implanting halogen ions into the insulating layer using the photoresist pattern as an ion implantation mask;
forming a via-hole exposing the first metal line by dry-etching the insulating layer using the photoresist pattern as an etch mask; and
forming a second metal line in the via-hole to be contacted with the first metal line.

2. The method of claim 1, wherein the halogen ion comprises at least one selected from the group consisting of F, Cl and Br.

3. The method of claim 2, wherein the halogen ions are implanted at a dose of 1E15˜1E18.

4. The method of claim 3, wherein the halogen ions are implanted at an energy of 5˜100 KeV.

5. The method of claim 4, wherein the dose and energy of the halogen ion implanting step are varied to enable the ions to be distributed at a uniform depth.

6. The method of claim 1, wherein the halogen ions are implanted at an energy of 5˜100 KeV.

7. The method of claim 1, wherein the insulating layer comprises an OSG (Organic Silicate Glass).

8. The method of claim 1, wherein the via-hole forming step comprises dry etching using an etching gas having CₓH_{y}F_{z} (where x, y, and z are each 0 or natural number) as a main component.

9. The method of claim 1, wherein the barrier layer comprises a single or stacked layer including at least one member selected from the group consisting of SiC, Si₃N₄, SiOC, SiOCH and SiON.

10. The method of claim 6, wherein the OSG comprises either SiOCH or SiOCH₃.

11. The method of claim 1, wherein the capping layer comprises a single or stacked layer including at least one member selected from the group consisting of SiO₂, SiC, SiN (Si₃N₄), SiOC, SiOCH and SiON.

12. The method of claim 8, wherein dry etching comprises a plasma etch using CₓH_{y}F_{z} and an additive gas selected from the group consisting of O₂, N₂, Ar and He.

13. The method of claim 1, wherein the barrier layer has a thickness of 100˜1,500 Å.

14. The method of claim 1, wherein the photoresist pattern defines a dense via-hole area and an isolated via-hole area.

15. A semiconductor device comprising:
a Cu line over a substrate;
a barrier layer covering the Cu line;
an insulating layer on the barrier layer, the insulating layer comprising ions of at least one halogen element implanted and distributed therein;
a capping layer on the insulating layer; and
a second Cu line in contact with the first Cu line and penetrating the barrier layer, the insulating layer and the capping layer.

16. The method of claim 15, wherein the insulating layer comprises an OSG (Organic Silicate Glass) layer.
